(19) United States
(12) Patent Application Publication
(10) Pub. No.: US 2010/0081284 A1
(43) Pub. Date: Apr. 1, 2010

(54) METHODS AND APPARATUS FOR IMPROVING FLOW UNIFORMITY IN A PROCESS CHAMBER

(75) Inventors: AJIT BALAKRISHNA, Sunnyvale, CA (US); Aniruddha Pal, Santa Clara, CA (US); James D. Carducci, Sunnyvale, CA (US); Semyon L. Kats, San Francisco, CA (US); Shahid Rauf, Pleasanton, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/240,090

(22) Filed: Sep. 29, 2008

(51) Int. Cl. H01L 21/3065; C23F 1/08; C23C 16/00

(52) U.S. Cl. 438/710; 156/345.26; 118/715; 118/728; 118/729; 257/E21.28

(57) ABSTRACT

Methods and apparatus for processing substrates are provided herein. In some embodiments, an apparatus for processing a substrate includes a flow equalizer configured to control the flow of gases between a process volume and an exhaust port of a process chamber. The flow equalizer includes at least one restrictor plate configured to be disposed in a plane proximate a surface of a substrate to be processed and defines an azimuthally non-uniform gap between an edge of the at least one restrictor plate and one of either a chamber wall or a substrate support when installed in the process chamber.

### BACKGROUND

1. Field

Embodiments of the present invention generally relate to semiconductor processing and, more particularly, to apparatus for processing substrates.

2. Description of the Related Art

Conventional process chambers that utilize a single pump to exhaust process gases from a side of the process chamber can lead to process non-uniformities (for example, non-uniform etch rates in an etch chamber) due, at least in part, to non-uniform flow of process gases in the process chamber. As the critical dimensions for semiconductor devices continue to shrink, process non-uniformities due to this effect are exacerbated by an increased need for more uniformly processed substrates.

Thus, there is a need in the art for an apparatus for processing substrates that can provide improved process uniformity.

### SUMMARY

Methods and apparatus for processing substrates are provided herein. In some embodiments, an apparatus for processing a substrate includes a flow equalizer configured to control the flow of gases between a process volume and an exhaust port of a process chamber. The flow equalizer includes at least one restrictor plate configured to be disposed in a plane proximate a surface of a substrate to be processed and defines an azimuthally non-uniform gap between an edge of the at least one restrictor plate and one of either a chamber wall or a substrate support when installed in the process chamber.

In some embodiments, an apparatus for processing a substrate includes a process chamber having a substrate support disposed in an inner volume thereof, the inner volume including a processing volume and a exhaust volume having an exhaust port disposed therein. A flow equalizer is disposed in the process chamber for controlling the flow of gases between the process volume and the exhaust port. The flow equalizer includes at least one restrictor plate disposed in a plane proximate the surface of a substrate to be processed and defining an azimuthally non-uniform gap between an edge of the at least one restrictor plate and one of either a chamber wall or the substrate support.

In some embodiments, a method for controlling flow in a process chamber includes providing a substrate to support surface of a substrate support disposed in an inner volume of a process chamber. The inner volume includes a processing volume and a exhaust volume having an exhaust port disposed therein. A gas is flowed into the processing volume. Flow non-uniformity over the substrate is reduced by flowing the gas from the processing volume to the exhaust volume past a flow equalizer disposed in the process chamber. The flow equalizer includes at least one restrictor plate disposed in a plane proximate a surface of the substrate and defines an azimuthally non-uniform gap between an edge of the at least one restrictor plate and one of either a chamber wall or the substrate support. Other and further embodiments and variations of the invention are described more fully below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1 and 1A depict apparatus for processing semiconductor substrates in accordance with some embodiments of the present invention.

FIGS. 2A-B depict apparatus for processing semiconductor substrates in accordance with some embodiments of the present invention.

FIGS. 3A-B depict schematic, top views of apparatus for processing semiconductor substrates in accordance with some embodiments of the present invention.

FIG. 4 depicts a schematic top view of an apparatus for processing semiconductor substrates in accordance with some embodiments of the present invention.

FIGS. 5A-E depict partial schematic side views of apparatus for processing semiconductor substrates in accordance with some embodiments of the present invention.

FIGS. 6A-B depict illustrative graphs depicting etch rate uniformity across a substrate during processing in a semiconductor substrate processing chamber without and with an apparatus in accordance with embodiments of the invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention generally relate to methods and apparatus for improving flow uniformity across a semiconductor substrate in a substrate processing chamber. The more uniform flow of process gases within the process chamber may advantageously facilitate more uniform flow of gases proximate the surface of a substrate, thereby facilitating more uniform processing of the substrate. The inventive apparatus may be utilized in any suitable process chamber having asymmetric pumping of exhaust. Suitable commercially available process chambers may include any of the DPS®, ENABLER®, ADVANTEDGE™, or other process chambers, available from Applied Materials, Inc. of Santa Clara, Calif.

Although described below with respect to a plasma etch reactor, other forms of plasma etch chambers may be modified in accordance with the teachings provided herein, including reactive ion etch (RIE) chambers, electron cyclotron resonance (ECR) chambers, and the like. Furthermore, the present invention may be useful in any processing chamber where flow control may improve process uniformity across the surface of a substrate during processing, such as atomic layer deposition (ALD) chambers, chemical vapor deposition (CVD) chambers, plasma enhanced chemical vapor deposition (PECVD) chambers, magnetically enhanced plasma processing chambers, and the like.

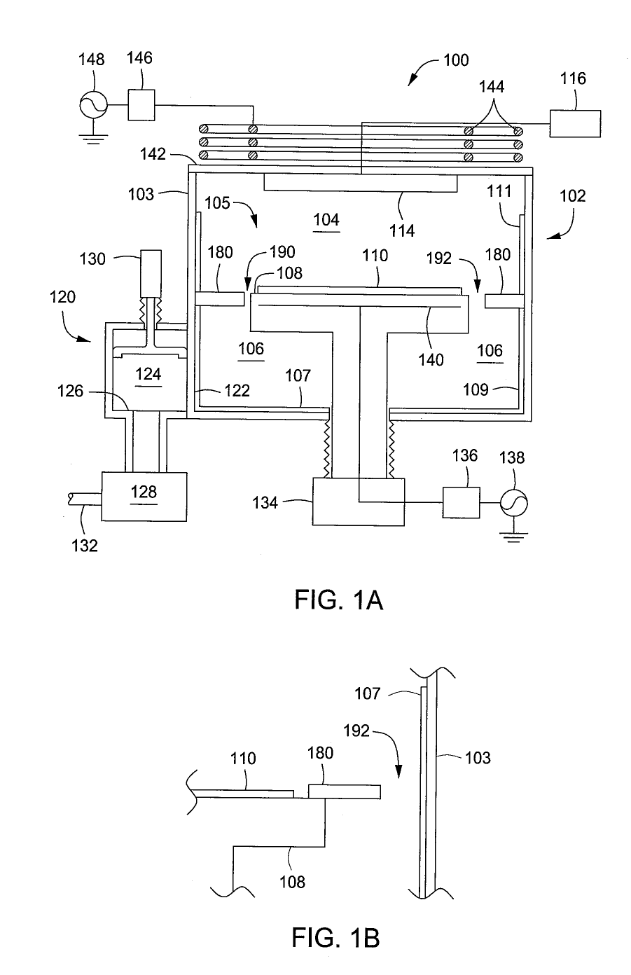

FIG. 1 depicts an apparatus 100 having a flow equalizer in accordance with some embodiments of the present invention disposed therein. The apparatus 100 may comprise a process chamber 102 having a processing volume 104 and an exhaust volume 106. The flow equalizer 180 is disposed between the processing volume 104 and exhaust volume 106 to facilitate the uniform flow of process gases therebetween.

The process chamber 102 has a chamber wall 103 defining an inner volume 105 that may include the processing volume 104 and the exhaust volume 106. The processing volume 104 may be defined, for example, between a substrate support 108 disposed within the process chamber 102 for supporting a substrate 110 thereupon during processing and one or more gas inlets, such as a showerhead 114 and/or nozzles provided at desired locations.

In some embodiments, the substrate support 108 may include a means for retaining the substrate 110 on the surface of the substrate support 108, such as an electrostatic chuck, a vacuum chuck, a substrate retaining clamp, or the like (not shown). In some embodiments, the substrate support 108 may include mechanisms for controlling the substrate temperature (such as heating and/or cooling devices, not shown) and/or for controlling the plasma flux proximate the substrate surface.

For example, in some embodiments, the substrate support 108 may include an RF bias electrode 140. The RF bias electrode 140 may be coupled to one or more bias power sources (one bias power source 138 shown) through one or more respective matching networks (matching network 136 shown). The one or more bias power sources may be capable of producing up to 12000 W at a frequency of about 2 MHz, or about 13.56 MHz, or about 60 MHz. In some embodiments, two bias power sources may be provided for coupling RF power through respective matching networks to the RF bias electrode 140 at a frequency of about 2 MHz and about 13.56 MHz. In some embodiments, three bias power sources may be provided for coupling RF power through respective matching networks to the RF bias electrode 140 at a frequency of about 2 MHz, about 13.56 MHz, and about 60 MHz. The at least one bias power source may provide either continuous or pulsed power. In some embodiments, the bias power source may be a DC or pulsed DC source.

In some embodiments, the position, or height, of the substrate support 108 within the process chamber 102 may be adjustable. For example, in some embodiments, a lift mechanism 134 may be coupled to the substrate support 108 to position the substrate support 108 in at least a lower position, for example, to facilitate the transfer of the substrate 110 into or out of the process chamber, such as through a slit valve (not shown), and an upper position, for example, to control the distance between the substrate 110 and the showerhead 114. The selection of the position of the substrate support 108 may alter the flow profile of a process gas on the substrate surface. Accordingly, in embodiments where the height of the substrate support 108 is changed, the ratio of the processing volume 104 to the exhaust volume 106 necessarily changes, which may result in a different flow profile across the substrate surface. In some embodiments, the flow equalizer 180 may be configured, for example, by design, to facilitate the uniform flow of process gases between the processing volume 104 and the exhaust volume 106 over the full range of heights accessible by the substrate support 108 (or a range of processing heights utilized during processing). For example, the flow equalizer 180 may be designed to provide an optimum flow uniformity over the aggregate range, and may not be optimized at a particular height accessible by the substrate support 108.

The one or more gas inlets (e.g., the showerhead 114) may be coupled to a gas supply 116 for providing one or more process gases into the processing volume 104 of the process chamber 102. Although a showerhead 114 is shown in FIG. 1, additional or alternative gas inlets may be provided such as nozzles or inlets disposed in the ceiling or on the sidewalls of the process chamber 102 or at other locations suitable for providing gases as desired to the process chamber 102.

In some embodiments, the apparatus 100 may utilize inductively coupled RF power for processing. For example, the process chamber 102 may have a ceiling 142 made from a dielectric material and a dielectric showerhead 114. The ceiling 142 may be substantially flat, although other types of ceilings, such as dome-shaped ceilings or the like, may also be utilized. An antenna comprising at least one inductive coil element 144 is disposed above the ceiling 142 (two co-axial elements 144 are shown). The inductive coil elements 144 are coupled to one or more RF power sources (one RF power source 148 shown) through one or more respective matching networks (matching network 146 shown). The one or more plasma sources may be capable of producing up to 5000 W at a frequency of about 60 MHz and/or about 162 MHz. In some embodiments, two RF power sources may be coupled to the inductive coil elements 144 through respective matching networks for providing RF power at frequencies of about 2 MHz and about 13.56 MHz.

The exhaust volume 106 may be defined, for example, as the chamber volume beneath the plane of the surface of the substrate support 108. The exhaust volume 106 may be fluidly coupled to an exhaust system 120, wherein the exhaust system 120 includes a pumping plenum 124 and an exhaust port 122. The exhaust volume 106 may be fluidly coupled to the pumping plenum 124 via the exhaust port 122.

The flow equalizer 180 may be disposed proximate the surface of the substrate support 108 (e.g., at the interface between the processing volume 104 and the exhaust volume 106) to facilitate the uniform flow of process gases from the processing volume 104 to the exhaust volume 106. For example, the flow equalizer 180 forms an azimuthally non-uniform gap between the flow equalizer 180 and the substrate support 108 (e.g., a radially non-uniform gap). The azimuthally non-uniform gap may be smaller proximate the exhaust port 122 (the smaller gap labeled 190 in FIG. 1) and larger at a distance farther from the exhaust port 122 (the larger gap labeled 192 in FIG. 1). In some embodiments, the size of the azimuthally non-uniform gap may vary inversely with the azimuthal position of the gap from adjacent the exhaust port 122 to further from the exhaust port 122 (e.g., corresponding to areas of low pressure and/or low flow when the flow equalizer 180 is not present). The azimuthally non-uniform gap is defined between an edge of the flow restrictor and the opposing surface defining the gap (e.g., either the substrate support or the chamber wall or liner, as described below).

The flow equalizer 180 provides a varied gap between the substrate support and chamber wall that is larger in areas that would otherwise have lower flow rates (e.g., further from the exhaust port 122) and smaller in areas that would otherwise have higher flow rates (e.g., closer to the exhaust port 122). The varying gap facilitates increasing the flow rate in areas that would otherwise be lower (by providing larger gap) while decreasing the flow rate in areas that would otherwise be higher (by providing smaller gap), thereby making the overall flow azimuthally (or radially) more uniform.

In the embodiments shown in FIG. 1, the process chamber 102 may have a liner 107 disposed adjacent to the chamber wall 103. The liner 107 may comprise any process suitable material, and in some embodiments, comprises a ceramic material. In some embodiments, the liner 107 may further comprise a lower liner 109 and an upper liner 111. The lower liner 109 may line a portion of the chamber wall 103 that includes the exhaust volume 104. The upper liner 111 may line a portion of the chamber wall 103 that includes the processing volume 106. In some embodiments, the flow equalizer 180 may be disposed and supported in a gap between the upper and lower liners 111, 109 proximate the boundary between the processing volume 104 and the exhaust volume 106. In such embodiments, the flow equalizer prevents the flow of process gases between the flow equalizer 180 and the chamber wall 103 and directs all flow from the processing volume 104 through the azimuthally non-uniform gap formed between the flow equalizer 180 and the substrate support 108. In some embodiments, the flow equalizer 180 may part of the liner 107 (or either of the upper or lower liners 111, 109). For example, the liner 107 may be a continuous structure having the flow equalizer extending therefrom. Alternatively, the flow equalizer 180 may be coupled to the chamber wall 103, with or without the presence of a liner.

Alternatively, and as depicted in a partial side view in FIG. 1A, the flow equalizer 180 may be disposed on the substrate support 108 thereby defining an azimuthally non-uniform gap between the flow equalizer 180 and the chamber wall 103 (or liner 107, when present). The azimuthally non-uniform gap is similar to the gap discussed above in FIG. 1, and may be larger at a distance farther from the exhaust port 122 (shown in FIG. 1).

Returning to FIG. 1, a vacuum pump 128 may be coupled to the pumping plenum 124 via a pumping port 126 for pumping out the exhaust gases from the process chamber 102. The vacuum pump 128 may be fluidly coupled to an exhaust outlet 132 for routing the exhaust as required to appropriate exhaust handling equipment. A valve 130 (such as a gate valve, or the like) may be disposed in the pumping plenum 124 to facilitate control of the flow rate of the exhaust gases in combination with the operation of the vacuum pump 128. Although a z-motion gate valve is shown, any suitable, process compatible valve for controlling the flow of the exhaust may be utilized.

The flow equalizer 180 facilitates uniform flow of the exhaust gases from the inner volume 105 of the process chamber 102. For example, the flow equalizer 180 may provide reduced variance of flow resistance azimuthally (or symmetrically) about the substrate support 108 (e.g., substantially equal flow resistance). Accordingly, in some embodiments, the azimuthally non uniform gap may have a substantially equal conductance, flow rate, or flow resistance across all portions of the gap, include those proximate to (gap 190) and farther (gap 192) from the exhaust port 122. As used herein, the term substantially equivalent, or substantially equal, is understood to mean within about 10 percent of each other).

The flow equalizer may be a singular component or may include many parts that together define the shape, or profile, or the flow equalizer. Generally, the flow equalizer partially fills the space between the substrate support and the chamber wall at the level of the support surface of the substrate support (or the surface of s substrate disposed thereon). The flow equalizer may be disposed adjacent to either the chamber wall (or liner), or the substrate support, such that all exhaust flowing from the processing volume to the exhaust volume flows through a gap defined between the flow equalizer and one of the substrate support or the chamber wall (or liner). The gap is generally azimuthally non-uniform and larger in regions of low pressure (e.g., farther from the pump port) and smaller in regions of high pressure (e.g., nearer to the pump port). The size and shape of the gap is defined by the profile, or shape, or the flow equalizer (as the support pedestal and the chamber wall geometry are generally fixed). The flow equalizer may have a profile (e.g., a shape when viewed from above) that is ovular, elliptical, circular, wavy, discontinuous, continuous, or the like. In some embodiments the profile is ovular or elliptical.

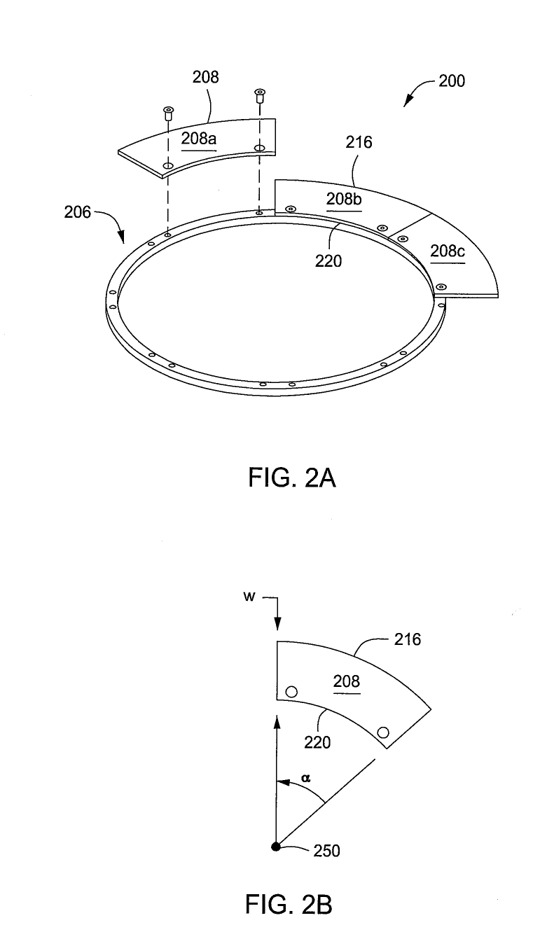

Embodiments of a flow equalizer which may be utilized in the apparatus 100 are provided in FIGS. 2-4 and described below. For example, FIG. 2A depicts an isometric, partially-exploded view of one embodiment of the flow equalizer 200. The flow equalizer 200 includes a support ring 206, and at least one restrictor plate 208 (three restrictor plates 208(a)-(c) illustratively shown). Although referred to herein as a plate, the at least one restrictor plate may generally include structures having other cross-sectional geometries configured to perform the same function. In some embodiments, the support ring 206 may generally circumscribe the substrate support 108 (for example as depicted in FIG. 1A). The support ring 206 may be coupled to the substrate support 108 in variety of ways including fastening with bolts, screws, adhesive, welding, clamps, and the like.

In some embodiments, the support ring 206 may be of varying thickness, and may be used to orient the angle of the at least one restrictor plate 208 with respect to the substrate support surface such that the at least one restrictor plate 208 is not parallel to a support surface of the substrate support, and, therefore, to the surface of a substrate being processed in the process chamber.

The at least one restrictor plate 208 operates as a baffle to alter the flow of gases passing over and around it. The at least one restrictor plate 208 may restrict a process gas flowing from a gas inlet (e.g., a showerhead or the like) to the exhaust port and is configured to provide uniform gas flow over the surface of the substrate 110 by providing maximum restriction of the gas flow near the exhaust port (e.g., regions of higher pressure) and minimal restriction to flow opposite the exhaust port (e.g., regions of lower pressure). The substantially equal gas flow alleviates the tendency of the plasma to be pulled towards the exhaust port.

In some embodiments, the at least one restrictor plate 208 is may be a singular ovular plate with a varying radial width oriented such that the maximum gas flow restriction is proximate the exhaust port and the minimum gas flow restriction is opposite the exhaust port. Alternatively, the at least one restrictor plate 208 may be a plurality of ovular segments of the same or varying radial widths that may be disposed proximate each other on the support ring 206 to form an ovular plate of the desired size and profile to optimize gas flow within the chamber during processing. It is contemplated that other configurations may be utilized in processing chambers with different geometries and varying exhaust port locations and or numbers.

The at least one restrictor plate 208 may be coupled to the support ring 206 in any conventional manner such as by bolting, screwing, bonding, or the like. It is contemplated that the at least one restrictor plate may be coupled directly to the substrate support surface or be supported by the liner without the support ring 206. In the embodiment depicted in FIG. 2A, the restrictor plates 208 are bolted through holes formed in the support ring 206 such that an inner edge 220 of the at least one restrictor plate 208 is maintained substantially flush with the inner edge of the support ring 206. The outer edge 216 of the at least one restrictor plate 208 and the chamber wall define the azimuthally non-uniform gap. Alternatively, the at least one restrictor plate 208 may be coupled to the support ring 206 proximate an outer edge of the at least one restrictor plate 208 such that the flow restrictor may be supported by the liner (as depicted in FIG. 1). In such embodiments, the inner edge 220 of the at least one restrictor plate 208 and the chamber wall define the azimuthally non-uniform gap.

In the embodiment depicted in FIG. 2A, the at least one restrictor plate comprises a plurality of restrictor plates (three illustratively shown, 208(a)-(c)) coupled to the support ring 206 and arranged next to each other to form an arc of a desired size. The particular size of the arc, or the sweep angle, will vary depending upon the process chamber geometry. The plurality of restrictor plates 208 shown in FIG. 2A sweep an angle of 45 degrees, such that the three restrictor plates 208(a), (b), (c) together comprise 135 degrees. However, the restrictor plates could be larger or smaller, or of varying profiles, leaving larger or smaller gaps as needed to optimize the pressure and flow in a particular chamber.

FIG. 2B, for example, depicts a plan view of one embodiment of a restrictor plate 208 for use in the flow equalizer 200. The size of the restrictor plate 208 is defined by an angle, α, measured from a center point 250, and a width, w, measured radially with respect to the center point 250. Altering the angle, α, will allow greater or lesser blockage of the air flow by a single plate. A smaller angle, α, allows for greater fine-tuning of the flow restrictor, while a larger angle, α, reduces parts. This allows for adjustment to find the optimum configuration. Moreover, once a particular configuration is determined, a single restrictor plate 208 may be fabricated with the angle, α, necessary to cover the desired area by itself.

In some embodiments, altering the width, w, changes the size of the azimuthally non-uniform gap defined by the flow equalizer 180. The width, w, may also vary within a single restrictor plate 208. This allows control of the gas flow around the edge of the flow equalizer and through the gap. In some embodiments, the width, w, of at least a portion of the at least one restrictor plate 208 may be sufficient to substantially close the gap, thereby substantially restricting gas flow through the gap. The variation in the size of the gap may be smooth, such as by using at least one restrictor plate with a tapering width. Alternatively, the variation in the size of the gap 192_{A} may be stepped, such as by using multiple restrictor plates each with a different width.

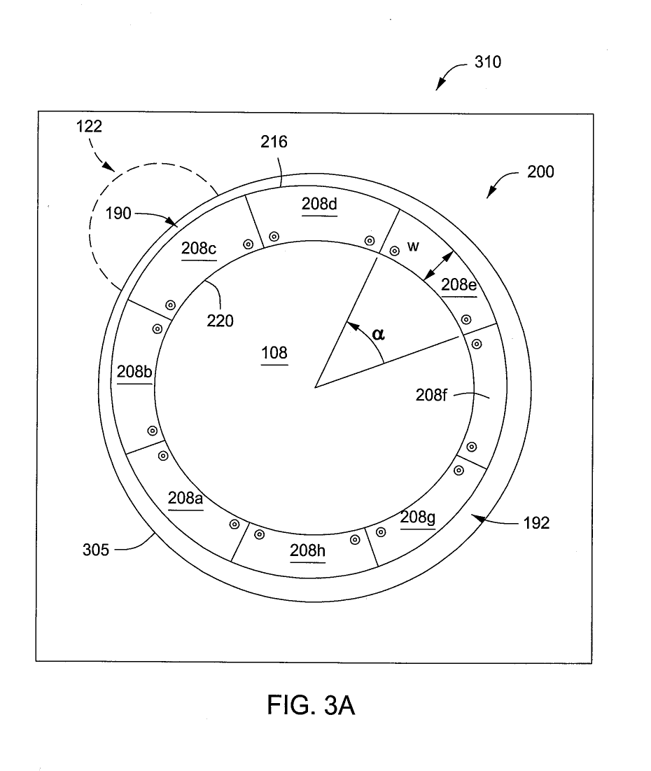

For example, FIG. 3A depicts a plan view of one embodiment of the flow equalizer 200 that may be disposed in a process chamber 310, similar to the process chamber 102 discussed above. FIG. 3A illustrates how a series of restrictor plates 208(a)-(h) can be arranged on a support ring (not shown) to control the pressure and velocity of air flowing over the surface of a substrate (not shown) disposed on the substrate support 108 in the process chamber 310. Alternatively, the restrictor plates 208(a)-(h) can be coupled directly to the substrate support or to the liner, as discussed above with respect to FIGS. 1 and 1A.

In this embodiment, eight restrictor plates 208(a)-(h) are illustratively abutted to substantially surround the substrate support 108. Each restrictor plate has an angle, α, of about 45 degrees, such that the assembled restrictor plates 208 surround about 360 degrees, or about the entire substrate support 108. Each restrictor plate also has a width, w, that defines the size of the azimuthally non uniform gap formed between the outer edge of each restrictor plate and the chamber wall 305 or optionally a liner (not shown in FIG. 3). The width, w, of a restrictor plate proximate the exhaust port 122 is greater than that of a restrictor plate farther from pumping port 122. As such, the gap 190 formed between an outer edge 216 of the restrictor plate 208(c) and the chamber wall 305 is smaller than the gap 192 formed by restrictor plate 208(g) located opposite the exhaust port 122. The restrictor plates 208 are situated such that any gap that may exist between the inner edge 220 of the restrictor plates 208 and an outer edge of the substrate support 108 is substantially closed.

Alternatively, FIG. 3B depicts a plan view of another embodiment of a flow equalizer 300 disposed in the process chamber 310. In this embodiment, the restrictor plate 312 is a unitary component which has an ovular profile for optimizing air pressure and velocity across the surface of a substrate disposed on a substrate support 108 in a process chamber 310. The width, w, of the restrictor plate 312 may vary in any amount, smoothly or discontinuously, along any portion thereof. In the embodiment depicted in FIGS. 3B, the width of the restrictor plate 312 tapers smoothly from a maximum width w₁ to a diametrically opposed minimum width w₂. The restrictor plate 312 is oriented such that the maximum width w₁ is disposed proximate the exhaust port 122, leaving only a small gap 190 near the exhaust port 122 and a much larger opening 192 disposed opposite the exhaust port 122.

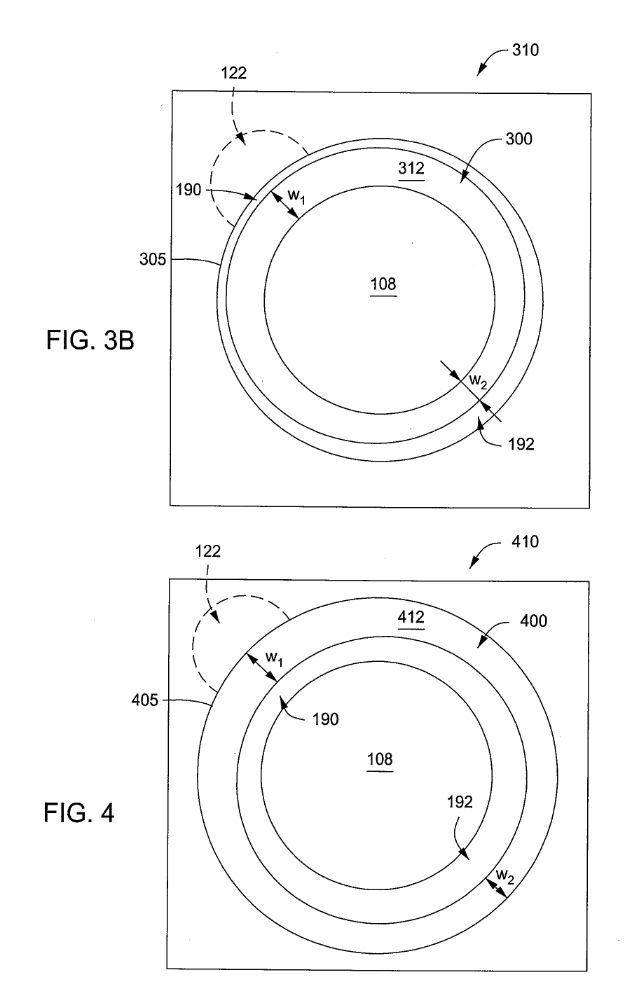

Although shown in FIGS. 3A-B as being disposed on the substrate support, in some embodiments, the flow equalizer may be disposed adjacent to a chamber wall, and may form an azimuthally non-uniform gap between the flow equalizer and the substrate support. For example, FIG. 4 depicts a plan view of one embodiment of a flow equalizer 400 that may be disposed in a process chamber 410, similar to the process chambers 102, 310 discussed above. This embodiment illustrates how a unitary restrictor plate 412 having an ovular profile can be configured to control the pressure and velocity of air flowing over the surface of a substrate (not shown). The flow equalizer 400 may be disposed in the gap between an upper and lower liner (see FIG. 1), or alternatively may be fastened to the chamber wall at a height proximate the boundary between the processing volume and the exhaust volume. The unitary restrictor plate can also be a series of restrictor plates (not shown), wherein the restrictor plates may vary in any amount, smoothly or discontinuously, along any radial section in accordance with embodiments described above.

In some embodiments, and as depicted in FIG. 4, the restrictor plate 412 may be a unitary component which has an ovular profile for optimizing air pressure and velocity across the surface of a substrate disposed on the substrate support 108. The width, w, of the restrictor plate 412 may vary in any amount, smoothly or discontinuously, along any radial section. In the embodiment depicted in FIG. 4, the width of the restrictor plate 412 tapers smoothly from a maximum width w₁ to a diametrically opposed minimum width w₂. The restrictor plate 412 is oriented such that the maximum width w₁ is disposed proximate the exhaust port 122, leaving only a small gap 190 near the exhaust port 122. The gap 190 is defined between the inner edge 416 of the restrictor plate 412 and the substrate support 108. A larger gap 192 is disposed opposite the exhaust port 122. The restrictor plate 412 need not be a unitary component and may, for example, be a plurality of restrictor plates as described above for the embodiments of FIG. 2-3.

Referring back to FIGS. 1 and 1A, the flow equalizer 180 may be anchored to at least one of the chamber wall 103, the liner 107, or the substrate support 108 using screws, adhesive, fasteners, clamps, and the like. Alternatively, the flow equalizer 180 may merely rest upon the liner 107 or the substrate support 108 without the use of additional fasteners. In addition, various other embodiments for disposing and/or supporting a flow equalizer in a chamber are provided herein.

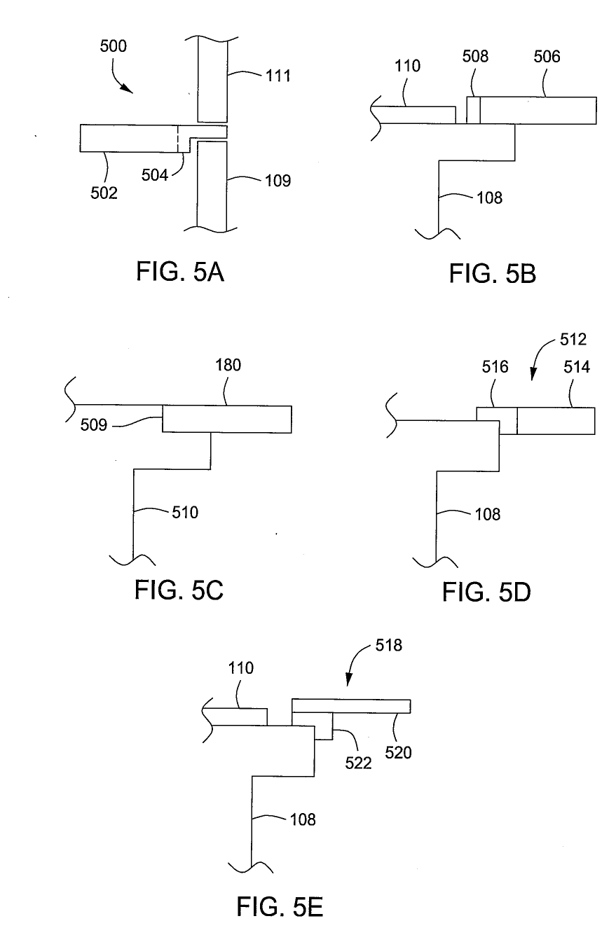

For example, in FIG. 5A, a flow restrictor 500 may be disposed in the gap between the upper liner 111 and the lower liner 109. In some embodiments, the flow restrictor 500 may rest upon the lower liner 109. In some embodiments, the flow restrictor 500 may have a notched portion at one end that can be inserted into the gap between the upper and lower liners. In some embodiments, the flow restrictor 500 comprises a restrictor plate 502 and a bracket 504, the bracket 504 resembling the shape of the notched portion described above. The restrictor plate 502 is consistent with the embodiments described above, and may be a unitary component, a series of restrictor plates, or the like. The bracket 504 may be an annular ring. Alternatively, a plurality of brackets 504 may be provided for coupling the restrictor plate 502 to the liner, or to the chamber wall at desired locations. The restrictor plate 502 may be coupled to the bracket 504 in any suitable fashion, such as by screws, adhesive, fasteners, clamps, or the like.

In some embodiments, as illustrated in FIG. 5B, a flow equalizer 506 may be coupled to the substrate support 108 via guide ring 508. In some embodiments, the guide ring 508 may be a unitary component having a diameter less than that of the substrate support surface. The flow equalizer 506 may be coupled to the guide ring 508 in any suitable fashion, such as by screws, adhesive, fasteners, clamps, friction fit, or the like. Alternatively, the flow equalizer 506 may be integrally formed with the guide ring 508. In some embodiments, the guide ring 508 may include a plurality of guide pins protruding from the substrate support surface. The flow equalizer 506 may have holes disposed therethrough proximate an inner edge (not shown), wherein the flow restrictor 506 can be coupled to the substrate support surface by inserting the guide pins into corresponding holes. Alternatively, the flow equalizer 506 may be press-fit against outer surfaces of the guide pins along the inner edge of the flow equalizer 506.

In some embodiments, illustrated in FIG. 5C, a substrate support 510 may include a notch 509 that circumscribes the edge of the substrate support surface, and capable of accepting the flow equalizer 180. The flow equalizer 180 may be any of the embodiments described above, such as a singular restrictor plate or a plurality of restrictor plates, and may be press-fit along an inner edge to the notch 509, or alternatively, anchored via fasteners, screws, adhesives, clamps, or the like.

In FIG. 5D, a flow equalizer 512 may be disposed on an edge of the substrate support 108. The flow equalizer 512 may have a notched portion at one end. The notched portion may be coupled to the edge of the substrate support surface via methods described above, such as by friction, fasteners, adhesives, or the like. Alternatively, and as depicted in FIG. 5D, the flow equalizer 512 may comprise a restrictor plate 514 and a bracket 516. The restrictor plate 514 may be similar to the embodiments described above. The bracket 516 may be similar to the notched portion described above in FIG. 5A, and may be coupled to the restrictor plate 514 at an inner edge (e.g., the edge closest to the substrate support).

In FIG. 5E, a flow equalizer 518 may be disposed along the edge of a substrate support 108, and may include a support ring 522 and a restrictor plate 520. The support ring 522 and the restrictor plate 520 may be similar to embodiments described above in FIGS. 2-3. The support ring 522 may circumscribe the substrate support surface along an outer edge thereof, and may further comprise a notch. The notch may be configured to fit over the edge of the substrate support surface. The flow equalizer 518 may be disposed atop the support ring 522 and flush with the inner edge thereof. In some embodiments, the flow equalizer 518 may be coupled to the support ring 522 and/or the substrate support surface via fasteners, adhesives, clamps, screws, or the like. In some embodiments, the support ring 522 may be press fit to the edge of the substrate support surface at the notch.

Thus, as described in the embodiments above, a flow equalizer facilitates substantially uniform flow of a process gas across the surface of a substrate disposed on a substrate support via the formation of an azimuthally non-uniform gap that at least partially circumscribes the substrate support. The varied gap width provides similar flow resistance for a process gas to traverse the gap and reach the pump, thereby improving process characteristics such as pressure and/or velocity profiles above the substrate during processing. In some embodiments, a substantially uniform flow means a ratio of a maximum flow to a minimum flow through the flow equalizer gap of less than or equal to about 1.2, or in some embodiments, less than or equal to about 1.15, or in some embodiments, less than or equal to about 1.1. The measurement of the flow through the gap may be determined by modeling rather than by actual in-situ measurements.

For example, in some embodiments, flowing a gas from a processing volume of a processing chamber to an exhaust volume of the processing chamber through a single azimuthally non-uniform gap having a width that varies inversely with the distance of the gap from a pumping port of the process chamber. The azimuthally non-uniform gap is defined between an edge of a flow equalizer disposed in the process chamber and one of either a chamber wall or a substrate support disposed in the process chamber. The flow equalizer may be disposed in a plane proximate a support surface of the substrate support. As another example, in some embodiments, a gas may be flowed into the processing volume of the process chamber. Flow non-uniformity over the substrate may be reduced by flowing the gas from the processing volume to the exhaust volume past a flow equalizer disposed in the process chamber. The flow equalizer includes at least one restrictor plate disposed in a plane proximate a surface of the substrate and defines an azimuthally non-uniform gap between an edge of the at least one restrictor plate and one of either a chamber wall or the substrate support.

For an additional example, referring to FIGS. 1 and 4, in operation, a substrate (such as substrate 110) may be disposed on the substrate support 108 and one or more process gases may be introduced into the processing volume 104 via the showerhead 114 (and/or other gas inlets). The substrate 110 may then be processed by the process gases, which may be in a plasma or non-plasma state, such as by etching the substrate, depositing a layer of material on the substrate, treating the substrate, or otherwise processing the substrate as desired. As the process gases are utilized to process the substrate, undesirable constituents (e.g., exhaust gases) in the processing volume 104 (such as excess unreacted process gases, process gas constituents or components, processing by-products, decomposed or broken down process gases or processing by-products, or the like) may be exhausted from the process chamber 102 through the exhaust system 120. Although referred to herein as exhaust gases, it is contemplated that liquid or solid matter may also be entrained within the exhaust gases and are included within the scope of the term exhaust gases.

Referring to any embodiments of the flow equalizer as discussed above (for example, the flow equalizer 180 depicted in FIG. 1 or 1A) the ratio between the processing volume 104 and the exhaust volume 106 may change as the height of the substrate support 108 is adjusted, for example, to facilitate desired processing positions and/or conditions. As discussed above, the flow equalizer, by way of design may be optimized to provide substantially uniform flow between the processing volume 104 and the exhaust volume 106 over the aggregate range of height, and not necessary optimized for uniform flow at a particular height in the range. Alternatively, when an optimized uniform flow is desired at a particular height of the substrate support 108, a flow equalizer having an optimized azimuthally non-uniform gap for the particular height and/or process conditions such as process gas flow rates and the like, may be utilized with a desired process being performed in the chamber 102. As such, if another process is desired which may require a different height and/or process conditions, the existing flow equalizer may be replaced with new flow equalizer that is optimized for the different height and/or process conditions.

Without the use of the inventive apparatus disclosed herein, the location of the showerhead, substrate support, and exhaust port of conventional process chambers causes an uneven distribution of pressure and velocity of the process gases across the surface of the substrate as the gases flow into and out of the process chamber. It is believed that this uneven pressure and velocity distribution affects the distribution of process gases in the chamber (for example, the location of a plasma or the uniformity of gaseous compositions in the chamber) and, therefore, the uniformity of the process being performed (for example, etch rate uniformity, deposition uniformity, or the like).

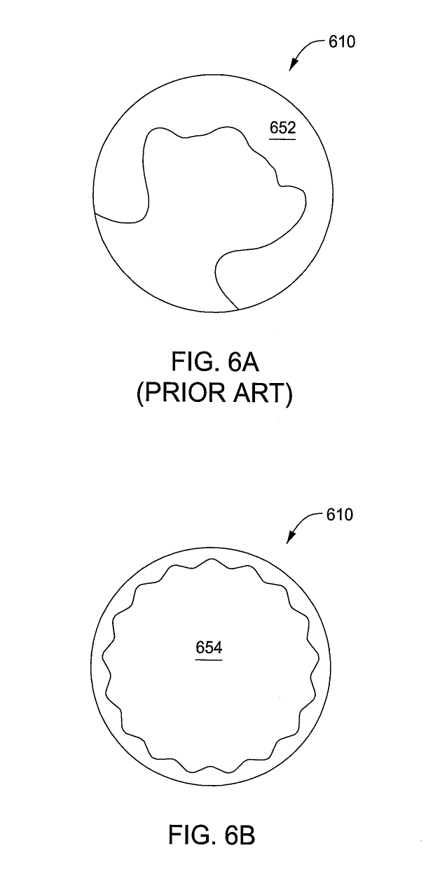

For example, FIGS. 6A-B are graphic representations of measurements taken which show the etch rate uniformity across the surface of a substrate with and without the use of an apparatus as described herein in accordance with embodiments of the invention. FIG. 6A shows an area of greater etch rate 652 on the surface of a substrate 610 in a conventional side-pumping process chamber. As can be seen from the figure, the reactive species has moved to one side of the substrate 610 due to the non-uniform gas flow within the chamber. This offset in location of the reactive species causes non-uniformity in the etch rate of the substrate 610, as indicated by the area of greater etch rate 652. FIG. 5B shows the improved area of greater etch rate 654 on the surface of a substrate 610 with the use of an apparatus as described herein in accordance with embodiments of the present invention. As can be seen in this figure, the reactive species is centered over the surface of the substrate 610 and results in a much more uniform area of greater etch rate 654.

Thus, flow equalizers for processing substrates have been provided herein that provides improved uniformity of gas flow proximate the surface of a substrate. The improved uniformity of gas flow facilitates improvement of substrate processing, such as etching, deposition, or other processes that may benefit from uniformity of gas flow.

While the foregoing is directed to embodiments of the present invention, other and further embodiments of the invention may be devised without departing from the basic scope thereof, and the scope thereof is determined by the claims that follow.

What is claimed is:

1. Apparatus for processing a substrate, comprising:
a flow equalizer configured to control the flow of gases between a process volume and an exhaust port of a process chamber, the flow equalizer comprising at least one restrictor plate configured to be disposed in a plane proximate a surface of a substrate to be processed and defining an azimuthally non-uniform gap between an edge of the at least one restrictor plate and one of either a chamber wall or a substrate support when installed in the process chamber.

2. Apparatus for processing a substrate, comprising:
a process chamber having a substrate support disposed in an inner volume thereof, the inner volume including a processing volume and a exhaust volume having an exhaust port disposed therein; and
a flow equalizer disposed in the process chamber for controlling the flow of gases between the process volume and the exhaust port, the flow equalizer comprising at least one restrictor plate disposed in a plane proximate the surface of a substrate to be processed and defining an azimuthally non-uniform gap between an edge of the at least one restrictor plate and one of either a chamber wall or the substrate support.

3. The apparatus of claim 2, wherein the at least one restrictor plate is wider at a first portion of the restrictor plate proximate the exhaust port and narrower at a second portion of the restrictor plate opposite the exhaust port.

4. The apparatus of claim 2, wherein the flow equalizer further comprises a support ring coupled to the at least one restrictor plate.

5. The apparatus of claim 4, wherein the at least one restrictor plate is wider at a first portion of the restrictor plate proximate the exhaust port and narrower at a second portion of the restrictor plate opposite the exhaust port.

6. The apparatus of claim 4, wherein the flow restrictor comprises a plurality of restrictor plates that together define the profile of the flow restrictor.

7. The apparatus of claim 2, wherein the flow equalizer is disposed adjacent to the chamber wall and the azimuthally non uniform gap is formed between the at least one restrictor plate and the substrate support.

8. The apparatus of claim 7, wherein the flow equalizer is coupled to the chamber wall and the azimuthally non uniform gap is formed between the at least one restrictor plate and the substrate support.

9. The apparatus of claim 7, wherein the flow restrictor is disposed between an upper liner and a lower liner adjacent the chamber wall.

10. The apparatus of claim 9, wherein the flow restrictor further comprises a bracket coupled to the at least one restrictor plate, the bracket supporting the flow restrictor between the upper liner and the lower liner.

11. The apparatus of claim 2, wherein flow equalizer is coupled to the substrate support and the azimuthally non uniform gap is formed between the at least one restrictor plate and the chamber wall.

12. The apparatus of claim 2, wherein flow equalizer is supported by the substrate support and the azimuthally non uniform gap is formed between the at least one restrictor plate and the chamber wall.

13. The apparatus of claim 12, wherein the flow equalizer comprises a plurality of restrictor plates that together define a profile of the flow equalizer.

14. The apparatus of claim 12, wherein the substrate support further comprises a notch that circumscribes the edge of a support surface of the substrate support, wherein an inner edge of the flow equalizer is disposed in the notch.

15. The apparatus of claim 12, wherein the substrate support further comprises at least one of a guide ring or a plurality of guide pins for interfacing with the flow equalizer.

16. The apparatus of claim 12, wherein the flow equalizer further comprises a notch configured to interface with an edge of the substrate support.

17. The apparatus of claim 12, wherein the flow restrictor further comprises a bracket coupled to the at least one restrictor plate, the bracket supporting the flow restrictor and interfacing with the substrate support.

18. The apparatus of claim 2, wherein the at least one restrictor plate is at least one of parallel or at an angle relative to the surface of the substrate support.

19. The apparatus of claim 2, wherein a flow rate of a process gas provided to the process chamber and flowing through the azimuthally non-uniform gap is substantially uniform proximate a support surface of the substrate support.

20. The apparatus of claim 2, wherein the flow equalizer is disposed on the substrate support and wherein the substrate support is configured to move vertically.

21. The apparatus of claim 2, wherein the flow equalizer is disposed adjacent the chamber wall and wherein the substrate support is configured to move vertically.

22. A method for processing a substrate in a process chamber, comprising:
providing a substrate to a support surface of a substrate support disposed in an inner volume of a process chamber, the inner volume including a processing volume and a exhaust volume having an exhaust port disposed therein;
flowing a gas into the processing volume; and
reducing flow non-uniformity over the substrate by flowing the gas from the processing volume to the exhaust volume past a flow equalizer disposed in the process chamber, the flow equalizer comprising at least one restrictor plate disposed in a plane proximate a surface of the substrate and defining an azimuthally non-uniform gap between an edge of the at least one restrictor plate and one of either a chamber wall or the substrate support.

23. The method of claim 22, further comprising:
forming a plasma in the process chamber to process the substrate while reducing flow non-uniformity over the substrate.

24. The method of claim 22, wherein reducing flow non-uniformity over the substrate further comprises:
disposing the flow equalizer adjacent the chamber wall to define the azimuthally non-uniform gap between the edge of the at least one restrictor plate and the substrate support.

25. The method of claim 22, wherein reducing flow non-uniformity over the substrate further comprises:
disposing the flow equalizer adjacent the substrate support to define the azimuthally non-uniform gap between the edge of the at least one restrictor plate and the chamber wall.
